(19) United States
(12) Patent Application Publication
(10) Pub. No.: US 2009/0035916 A1
(43) Pub. Date: Feb. 5, 2009

(54) METHOD FOR MANUFACTURING SEMICONDUCTOR DEVICE HAVING FIN GATE

(76) Inventor: Jung Nam KIM, Gyeonggi-do (KR)

Correspondence Address: LADAS & PARRY LLP, 224 SOUTH MICHIGAN AVENUE, SUITE 1600, CHICAGO, IL, 60604, US

(21) Appl. No.: 12/118,779

(22) Filed: May 12, 2008

(30) Foreign Application Priority Data
Aug. 3, 2007 (KR) 10-2007-0078232
Mar. 19, 2008 (KR) 10-2008-0025441

(51) Int. Cl. H01L 21/762; H01L 21/302

(52) U.S. Cl. 438/424; 438/706; 257/E21.214; 257/E21.545

(57) ABSTRACT

When manufacturing a semiconductor device, an isolation layer is formed on a semiconductor substrate to define an active region that includes gate forming area. Portions of the isolation layer that are adjacent to the gate forming area of the active region are etching by a dry cleaning process which utilizes NH₃ gas and HF gas to form a fin pattern, in which the gate forming area of the active region protrude. Gate is formed on the fin pattern and on the etched portions of the isolation layer to surround the fin pattern. The dry cleaning process has a high etch selectivity between the semiconductor substrate and the isolation layer, which allows for the effective adjustment of the height of the fin patterns.

### CROSS-REFERENCE TO RELATED APPLICATIONS

The present application claims priorities to Korean patent application numbers 10-2007-0078232 filed on Aug. 3, 2007 and 10-2008-0025441 filed on Mar. 19, 2008, which are incorporated herein by reference in their entireties.

### BACKGROUND OF THE INVENTION

The present invention relates to a method for manufacturing a semiconductor device, and more particularly to a method for manufacturing a semiconductor device which can adjust the height of fin patterns when forming fin gates.

Higher density integration of semiconductor devices leads to decreased transistor channel lengths and increased doping concentrations in the source and drain regions. This then likely causes the problematic charge sharing phenomenon between the source and drain regions that degrades the controllability of gates due to a short channel effect (i.e., abrupt decrease of the threshold voltage). Also, the refresh characteristics are deteriorated due to increased junction leakage current caused by the increased number of electric fields in the junction regions. Unless the problems described above are removed, it would be difficult to achieve the threshold voltage required in a highly integrated semiconductor device by using a transistor having a conventional planar channel structure. Limitations that hinder improvement of the semiconductor device refresh characteristics would therefore still exist.

Thus, efforts were made in the past to realize a semiconductor device which would have a three-dimensional channel structure to enlarge the channel region. As a result, a semiconductor device having fin gates became known in the field of logic devices. In a semiconductor device having fin gates an active region protrudes when an isolation layer is etched. Gates are then formed to surround the protruding active region. When a semiconductor device utilizes fin gates, an effective channel width is increased, leading to an improved current drive characteristic and an increased threshold voltage margin.

Hereinafter is a description of a conventional method for manufacturing a semiconductor device having fin gates.

First, a semiconductor device having an isolation layer for defining the active region is prepared. Portions of the isolation layer corresponding to areas where gate is to be located are partially etched to form a fin pattern comprising a protruding active region. Fin gates are formed on the semiconductor substrate surrounding the fin pattern. Source and drain regions are formed in the active region on both sides of the fin gates.

As described above, the fin pattern is formed by etching a partial thickness of the isolation layer. The etching of the isolation layer is conducted simultaneously with etching of the active region in order to effectively increase the width of a channel. Therefore, when conducting the etching of the isolation layer and the active region, a high etch selectivity between an oxide layer and the semiconductor substrate made of Si must be used to obtain the desired height of the fin pattern.

However, in conventional methods, the etch selectivity between the oxide layer and the semiconductor substrate is not considered (low etch selectivity) when etching the isolation layer and the active region. Therefore, it is difficult to appropriately adjust the height of the fin pattern. Also, even if the etching thickness of the isolation layer is increased, to increase the height of the fin pattern; the etching loss of the active region increases, and thus the desired height of the fin pattern cannot be obtained.

### SUMMARY OF THE INVENTION

Embodiments of the present invention include a method for manufacturing a semiconductor device which can adjust the height of fin patterns when forming fin gates.

Additionally, embodiments of the present invention include a method for manufacturing a semiconductor device which improves the characteristics of fin gates, thereby improving the characteristics of a semiconductor device.

In one aspect, a method for manufacturing a semiconductor device having a semiconductor substrate with an isolation layer defining an active region including a gate forming area, the method comprises the step of etching portions of an isolation layer adjacent to the gate forming area of the active region using a dry cleaning process, to form a fin pattern wherein the gate forming area of the active region protrude, wherein the dry cleaning process uses NH₃ gas and HF gas.

The NH₃ gas and the HF gas are flowed 20˜40 sccm and 20˜40 sccm respectively.

The dry cleaning process can be conducted by adding Ar gas.

The Ar gas is flowed 10˜40 sccm.

The dry cleaning process is conducted under a pressure of 40˜80 mTorr for 30˜120 seconds.

In another aspect, a method for manufacturing a semiconductor device comprises the steps of forming an isolation layer on a semiconductor substrate to define an active region including gate forming area; etching portions of the isolation layer adjacent to the gate forming area of the active region using a dry cleaning process to form a fin pattern, in which the gate forming area of the active region protrude; and forming gates on the fin pattern and on the etched portions of the isolation layer to surround the fin pattern.

The dry cleaning process is conducted with a high etch selectivity between the semiconductor substrate comprising Si and the isolation layer comprising an oxide layer. Preferably, an etch rate of the oxide layer is faster than that of Si.

The dry cleaning process is conducted using NH₃ gas and HF gas.

The NH₃ gas and the HF gas is flowed 20˜40 sccm and 20˜40 sccm respectively.

The dry cleaning process can be conducted by adding Ar gas to the NH₃ gas and HF gas.

When the Ar gas is added, each of the NH₃ gas and HF gas is flowed at 20˜40 sccm, and the Ar gas is flowed at 10˜40 sccm.

The dry cleaning process is conducted under a pressure of 40˜80 mTorr for 30˜120 seconds.

Additionally, after the step of forming the isolation layer and before the step of forming the fin pattern, the method may further comprise the step of recessing the gate forming area in the active region.

### BRIEF DESCRIPTION OF THE DRAWINGS

FIG. 1 is a plan view showing a semiconductor device.

FIGS. 2A through 2D are cross-sectional views taken along line A-A′ of FIG. 1 shown for illustrating the processes in a method for manufacturing a semiconductor device in accordance with an embodiment of the present invention.

FIGS. 3A through 3D are cross-sectional views taken along line B-B′ of FIG. 1 shown for illustrating the processes in the method for manufacturing a semiconductor device in accordance with the embodiment of the present invention.

FIG. 4 is a graph explaining the effects of the present invention.

FIG. 5 is a cross-sectional view shown for illustrating a method for manufacturing a semiconductor device in accordance with another embodiment of the present invention.

### DESCRIPTION OF SPECIFIC EMBODIMENTS

In the present invention, a dry cleaning process using NH₃ gas and HF gas is conducted to etch the isolation layer. The dry cleaning process using the NH₃ gas and HF gas has high etch selectivity between Si and the oxide layer, and therefore it is possible to selectively etch an isolation layer comprising an oxide layer while minimizing the loss of the active region of a semiconductor substrate made of Si.

Accordingly, in the present invention, the height of the fin patterns formed by the protruding active region can be adjusted, such that the desired height of the fin patterns can be achieved, leading to improved characteristics in a semiconductor device having fin gates.

Hereafter, the specific embodiments of the present invention will be described in detail with reference to the attached drawings.

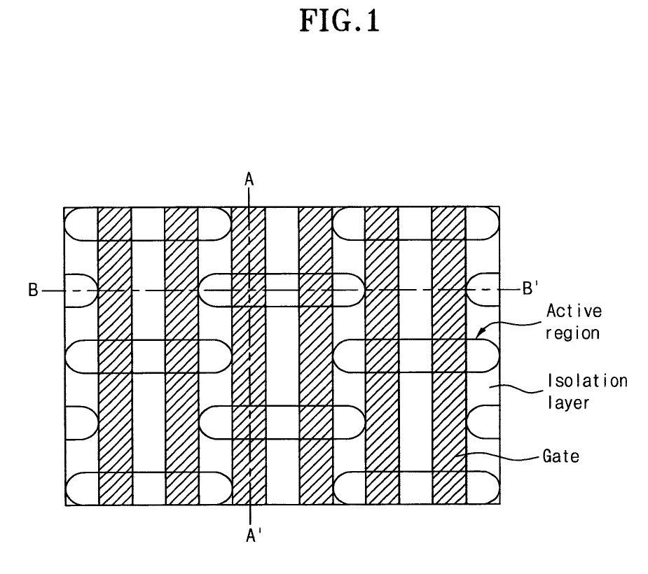

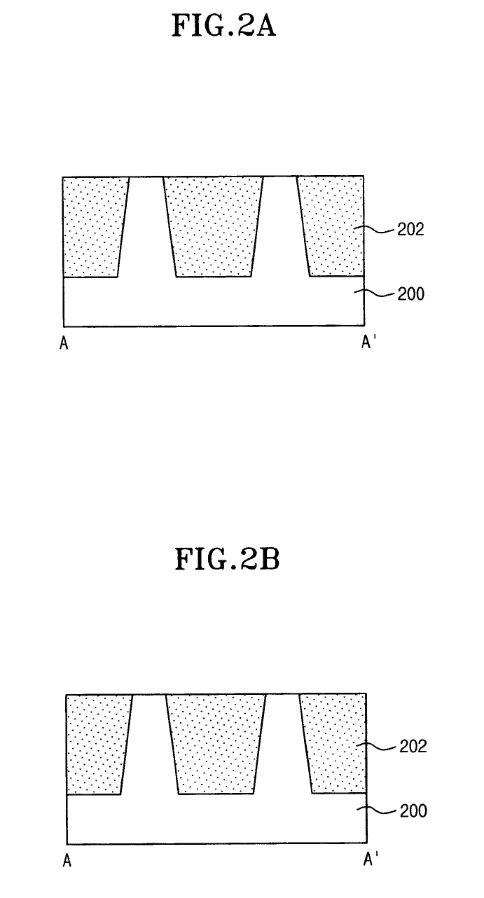

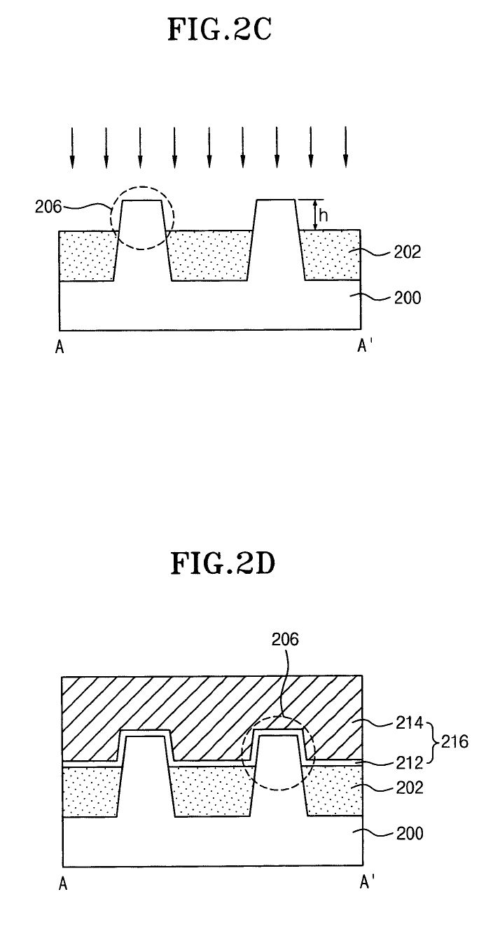

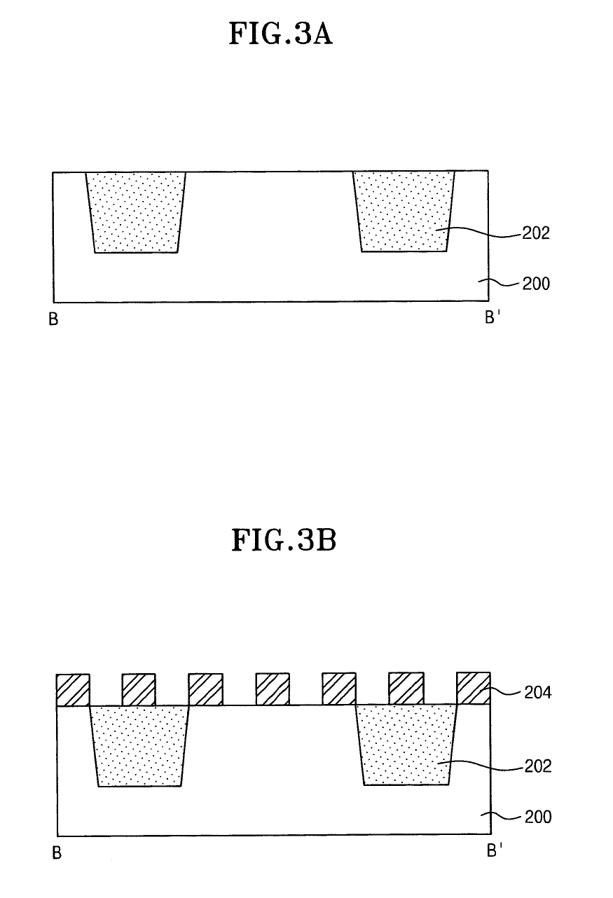

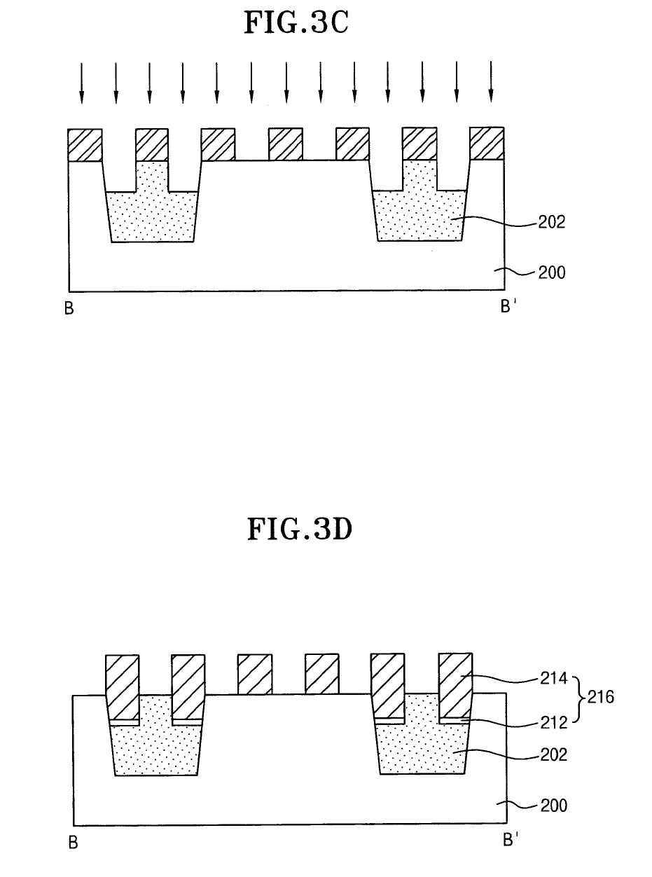

FIG. 1 is a plan view showing a semiconductor device. FIGS. 2A through 2D and FIGS. 3A through 3D are cross-sectional views taken along lines A-A′ and B-B′ of FIG. 1 respectively, shown for illustrating the processes in a method for manufacturing a semiconductor device in accordance with an embodiment of the present invention.

Referring to FIGS. 1, 2A, and 3A, a semiconductor substrate 200 is prepared. The semiconductor substrate 200 has an active region (which includes gate forming area) and an isolation region, and the semiconductor substrate 200 is made of Si. A pad oxide layer (not shown) and a pad nitride layer (not shown) are sequentially formed on the semiconductor substrate 200. The pad nitride layer and the pad oxide layer are then etched such that the isolation region of the semiconductor substrate 200 is exposed. The exposed portion of the isolation region of the semiconductor substrate 200 is etched using the etched pad nitride layer as an etch mask to define trenches. An insulation layer (for example, an oxide layer) is formed in the trenches, thereby forming an isolation layer 202. Thereafter, the pad nitride layer and the pad oxide layer are removed.

Referring to FIGS. 2B and 3B, a hard mask layer is formed on the semiconductor substrate 200 having the isolation layer 202. The hard mask layer is formed to have a stack structure comprising, for example, an amorphous carbon layer, an SiON layer, and a bottom anti-reflective coating (BARC) layer. The hard mask layer is etched to form a hard mask 204 that exposes the gate forming area of the active region and portions of the isolation layer 202 adjacent to the active region.

Referring to FIGS. 2C and 3C, a partial thickness of the exposed portions of the isolation layer 202 are etched using the hard mask 204 as an etch mask to form a fin pattern 206, in which the gate forming area of the active region protrude. Etching of the isolation layer 202 is conducted through a dry cleaning process using NH₃ gas and HF gas. It is preferred that the dry cleaning process (which uses NH₃ gas and HF gas) be conducted by adding Ar gas. The the NH₃ gas, HF gas, and Ar gas are flowed, for example, at 20˜40 sccm, 20˜40 sccm, and 10˜40 sccm respectively under a pressure of 40˜80 mTorr for of 30˜120 seconds.

The dry cleaning process using the NH₃ gas and HF gas is conducted not only on the isolation layer 202, but also on the active region. The dry cleaning process using the NH₃ gas and HF gas has a high etch selectivity between Si and an oxide layer (preferably, an etch rate of the oxide layer is faster than that of Si), and thus the dry cleaning process is conducted such that only the isolation layer 202 comprising an oxide layer is etched, and loss of the active region of the semiconductor substrate 200 made of Si is minimized.

Accordingly, in the present invention, the isolation layer 202 is etched without a substantial loss of the active region, and therefore the height ‘h’ of the fin pattern 206 can be effectively adjusted. Through this, the fin pattern 206 having the desired height can be easily formed.

Referring to FIGS. 2D and 3D, the hard mask 204 is removed from the resultant semiconductor substrate 200 formed with the fin pattern 206. A gate insulation layer 212 and a gate conductive layer 214 are formed sequentially on the semiconductor substrate 200 including the fin pattern 206. The gate conductive layer 214 and the gate insulation layer 212 are then etched to form line-type gates 216 surrounding the fin pattern 206.

Thereafter, while not shown in the drawings, a series of well-known subsequent processes are sequentially performed, including a source and drain forming process, and thereafter the manufacturing process of the semiconductor device according to the present invention is complete.

As described above, in the present invention etching the isolation layer using a dry cleaning process having a high etch selectivity of an oxide layer to Si to form the fin patterns allows for the effective adjustment of the height of the fin patterns. Accordingly, in the present invention, it is possible to improve the characteristics of a semiconductor device having fin gates formed to surround fin patterns.

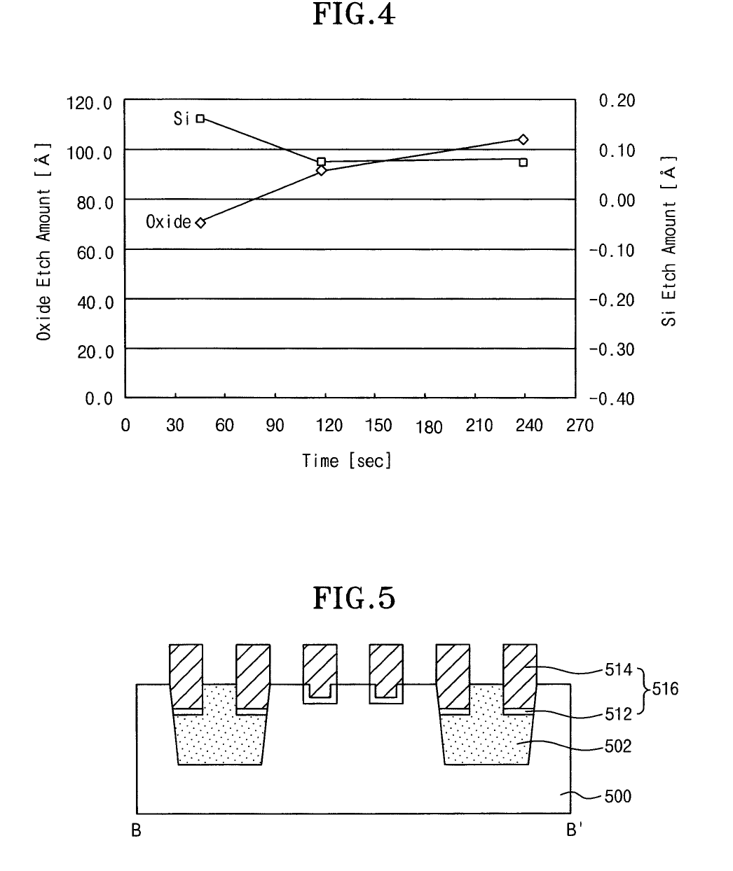

FIG. 4 is a graph explaining the effects of the present invention.

When the isolation layer is dry-cleaned using NH₃ gas and HF gas to form fin patterns, as can be readily seen from FIG. 4, an oxide layer is etched at a thickness of about 100 Å, whereas Si is etched at a small thickness less than 0.1 Å.

Therefore, FIG. 4 illustrates that when the dry cleaning process according to the present invention is conducted in order to form the fin patterns, the isolation layer can be selectively etched without a substantial loss of the active region. Accordingly, in the present invention, the height of the fin patterns can be effectively adjusted.

While the case of forming only fin gates was shown and explained in the above embodiment, it is to be noted that the present invention can also be applied when manufacturing a semiconductor device having a combined structure including recess gates and fin gates, as is shown for example in FIG. 5. In this case, after portions of an active region, which correspond to the gate forming area and are exposed through a hard mask, are first etched, portions of an isolation layer, which are adjacent to the active region, are etched using a dry cleaning process according to the present invention.

In FIG. 5, the reference numeral 500 designates a semiconductor substrate, 502 an isolation layer, 512 a gate insulation layer, 514 a gate conductive layer, and 516 gates.

In this case the isolation layer can be selectively etched using the dry cleaning process, and therefore the height of the fin patterns can be easily adjusted. Accordingly, it is possible to improve the characteristics of a semiconductor device having fin gates.

Although specific embodiments of the present invention have been described for illustrative purposes, those skilled in the art will appreciate that various modifications, additions, and substitutions are possible without departing from the scope and the spirit of the invention as disclosed in the accompanying claims.

What is claimed is:

1. A method for manufacturing a semiconductor device having a semiconductor substrate with an isolation layer defining an active region including a gate forming area, the method comprising the step of:
etching portions of the isolation layer adjacent to the gate forming area of the active region using a dry cleaning process, to form a fin pattern wherein the gate forming area of the active region protrude;
wherein the dry cleaning process uses NH₃ gas and HF gas.

2. The method according to claim 1, wherein the NH₃ gas and the HF gas are flowed 20˜40 sccm and 20˜40 sccm respectively.

3. The method according to claim 1, wherein Ar gas is added when conducting the dry cleaning process.

4. The method according to claim 3, wherein Ar gas is flowed 10˜40 sccm.

5. The method according to claim 1, wherein the dry cleaning process is conducted under a pressure of 40˜80 mTorr for 30˜120 seconds.

6. A method for manufacturing a semiconductor device, comprising the steps of:
forming an isolation layer on a semiconductor substrate to define an active region including a gate forming area;
etching portions of the isolation layer adjacent to the gate forming area of the active region using a dry cleaning process to form a fin pattern wherein the gate forming area of the active region protrude; and
forming gate on the fin pattern and on the etched portions of the isolation layer to surround the fin pattern.

7. The method according to claim 6, wherein the dry cleaning process is conducted with a high etch selectivity between the semiconductor substrate comprising Si and the isolation layer comprising an oxide layer.

8. The method according to claim 7, wherein an etch rate of the oxide layer is faster than that of Si.

9. The method according to claim 6, wherein the dry cleaning process is conducted using NH₃ gas and HF gas.

10. The method according to claim 9, wherein the NH₃ gas and the HF gas are flowed 20˜40 sccm respectively.

11. The method according to claim 9, wherein Ar gas is added when conducting the dry cleaning process.

12. The method according to claim 11, wherein the NH₃ gas, the HF gas and Ar gas are flowed 20˜40 sccm, 20˜40 sccm and 10˜40 sccm respectively.

13. The method according to claim 6, wherein the dry cleaning process is conducted under a pressure of 40˜80 mTorr for 30˜120 seconds.

14. The method according to claim 6, further comprising:
after the step of forming the isolation layer and before the step of forming the fin pattern:
recessing the gate forming area of the active region.
